(19) United States
(12) Patent Application Publication
(10) Pub. No.: US 2016/0118813 A1
(43) Pub. Date: Apr. 28, 2016

(54) System and Method Using Energy Harvest for Mobile Projector

(71) Applicant: Wireless Mobi Solution, Inc., San Diego, CA (US)

(72) Inventors: Mohammed Didarul Alam, San Diego, CA (US); Hongxuan Qian, San Diego, CA (US)

(73) Assignee: Wireless Mobi Solution, Inc., San Diego, CA (US)

(21) Appl. No.: 14/524,403

(22) Filed: Oct. 27, 2014

(51) Int. Cl. H02J 7/00; H05K 7/20

(52) U.S. Cl. CPC H02J 7/007; H02J 7/0052; H05K 7/20236

(57) ABSTRACT

A system and its method using waste heat energy to generate useful electricity for mobile projector is revealed; the purpose are two folds: first is to reduce the excessive heat, in order to increase the brightness; the second is to recycle the energy, so to extend the working hours between the recharges. The key component used is silicon based reversible heat pump diode, which can convert the electrical energy to heat energy, or from heat energy to electrical energy. Both hydrophilic and hydrophobic coatings are used to enhance the energy converting efficiency. One sample implementation combined with standard alone battery charger is described in details.

### FIELD OF THE INVENTION

The present patent application generally relates to application of energy harvest technologies and more specifically to a system and a method using heat energy to generate electricity for mobile projector, to reduce the heat, and increase the brightness.

### BACKGROUND

Battery life is the main issue, preventing the mobile projector to increase the brightness, since the bright the light is, the more heat will be generated, the heat from the LED light, from the DMD driver, from the battery itself, this invention propose to use the heat to regenerate the electricity, to recycle the energy. There are lots of inventions, such as, using the sun light or nano-friction to generate the electricity, but sun light and vibration are not always available^{[1]}. However, heat is always there, by using reverse using of the silicon diode, we can generate the electricity from the design. With silicon diode heat sink, not only the heat is eliminated, but also the power is generated.

With the past surge of the commercialization of the mobile devices, the continuing expansion of energy harvest applications, the component price has seen a steady decrease. Researchers are diligently working towards disruptive technology that has not previously been given substantial attention, including thermal diode electricity generator.

As an essential requirement for projection systems, brighter mobile devices with coordinated heat recycle pairs have been developed. The conventional projector system needs high noise fan^{[2]} and high capacity battery system^{[3]}, the new system utilize the heat recycle silicon diode, that can move the heat back to electricity without making any noise. This eliminates the noise, remove the holes, and allow water proof design as well.

In addition, it can be used in the similar mobile devices as well.

### SUMMARY

Considered broadly, a system for air cooling or water cooling with silicon thermal charging diode comprises a heating dissipating device, at least one cooling device, which is configured to communicate with each of the at least one humid sensor device, to determine a current environment between the lighting device and the printed circuit board, and to control the operating mode of the charging device according to the temperature difference. The projecting device is configured to sense the environment conditions such as wet or dry through at least one of the humidity sensor, to detect if water coolant needs to be added. The cooling device and each of the heating devices is configured to perform temperature difference needed for generating electricity. The heating device and each of the cooling devices is configured to form a dry and wet pair. The projecting device and mobile charging device are configured to deal with the charging and projecting at the same time. The dry pad is made of the water proof material, and the wet pad is made of hydrophilic material. The stand alone projecting device is paired up with any smart phone with related application to form the projecting system.

### BRIEF DESCRIPTIONS OF THE DRAWINGS

FIG. 1 is a diagram illustrating a hardware system that implements a clip on charger for intelligent mobile device in accordance with an embodiment of the present patent application.

FIG. 2 illustrates two flip shaped to form one cold pad for usage as a water proof cup coast, to cool itself.

FIG. 3 illustrates the software flow diagram of the projector.

FIG. 4 illustrates the hardware block diagram of the silicon cooler.

### DETAILED DESCRIPTION

Reference will now be made in detail to a preferred embodiment of the system and the method for silicon charger with intelligent mobile device disclosed in the present patent application, examples of which are also provided in the following description. Exemplary embodiments of the system and method disclosed in the present patent application are described in detail, although it will be apparent to those skilled in the relevant art that some features that are not particularly important to an understanding of the system and method may not be shown for the sake of clarity.

Furthermore, it should be understood that the system and method disclosed in the present patent application is not limited to the precise embodiments described below and that various changes and modifications thereof may be effected by one skilled in the art without departing from the spirit or scope of the protection. For example, elements and/or features of different illustrative embodiments may be combined with each other and/or substituted for each other within the scope of this disclosure.

Embodiments of the present patent application described hereafter present an active temperature sensor system coupled with charger actuators. The exact mobile devices for this purpose in the network have been developed. Silicon cooling end and heating end pairs are used to fulfill this charger control task, since the system has heat from lighting front end to be recycled.

Temperature balance techniques are provided according to one broad aspect of the present patent application and may be used on top of such solutions as water proof and water adhesive design for generating cold and hot sides more efficiently.

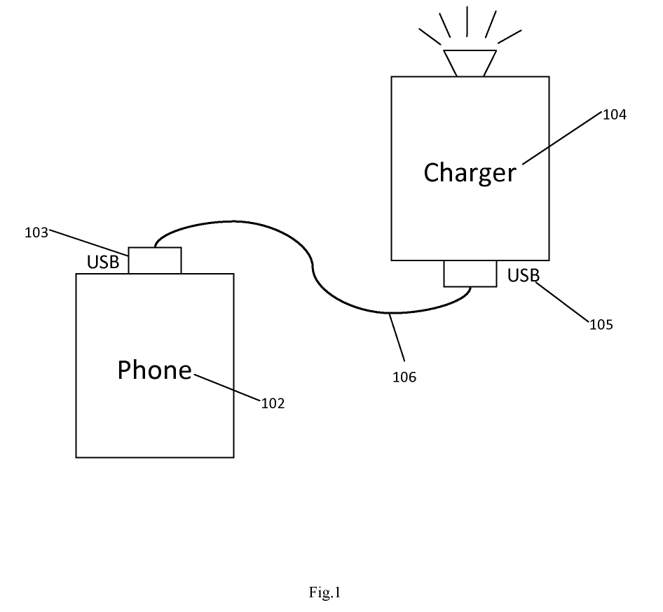

With reference to FIG. 1, a phone 102 is connected by USB 103, having a cable 106 connecting to charger 104, through USB 105.

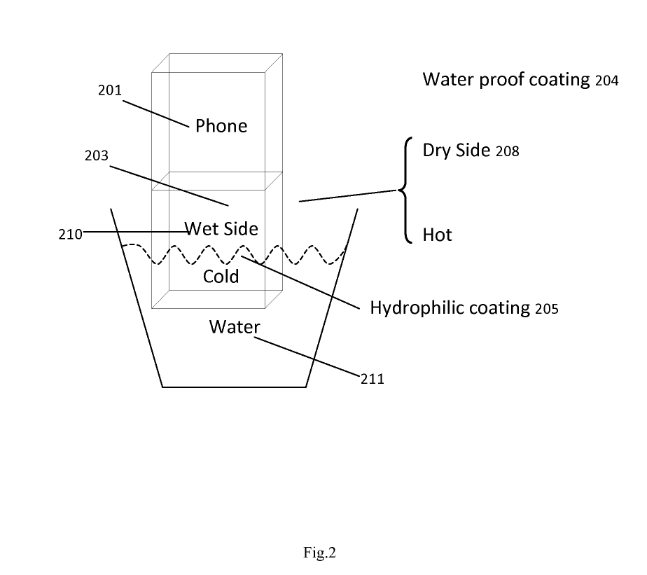

With reference to FIG. 2, a phone 201 is cooling down by water 211 through an auto-cool cold pad 203, whose dry side 208 is hot and wet side 210 cold, with water proof coating 204 on the dry side and hydrophilic coating 205 on the wet side.

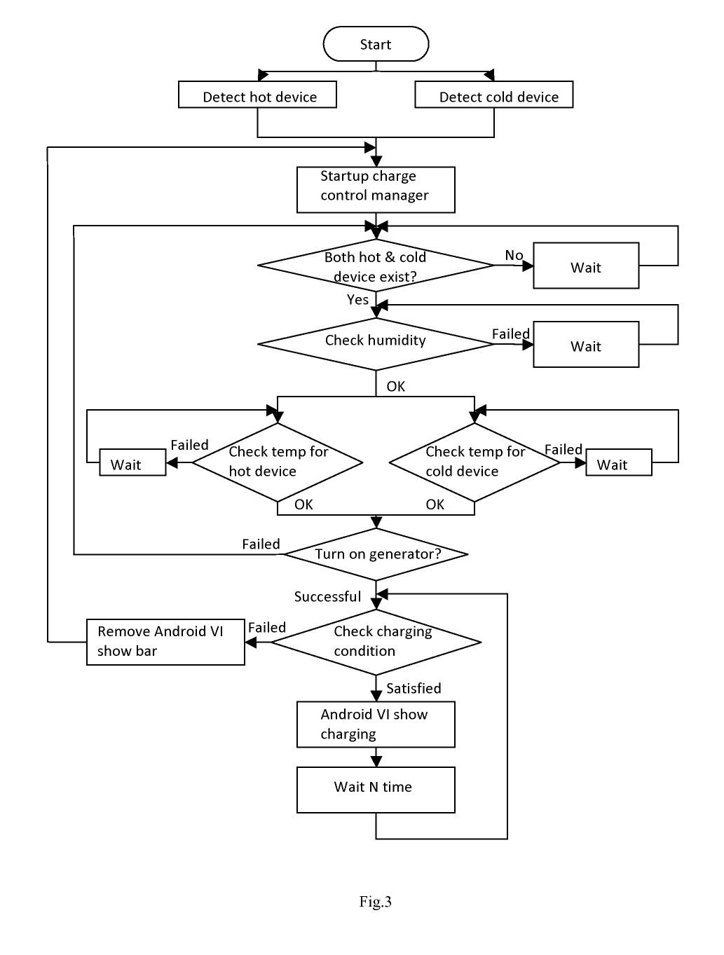

With reference to FIG. 3, the software flow diagram illustrates a typical charging procedure. First of all, the existence of both hot device and cold device must be guaranteed, then startup control manager and check humidity and device temperature. Each of the requirement must be met to satisfy a proper condition to charge, otherwise wait until requirement met. Generator should be turned on after requirements met, if failed, restart charge control manager. Once generator prepared, keep monitoring if charging condition still satisfied. Begin charging when satisfied or go back to the first step if charging finished.

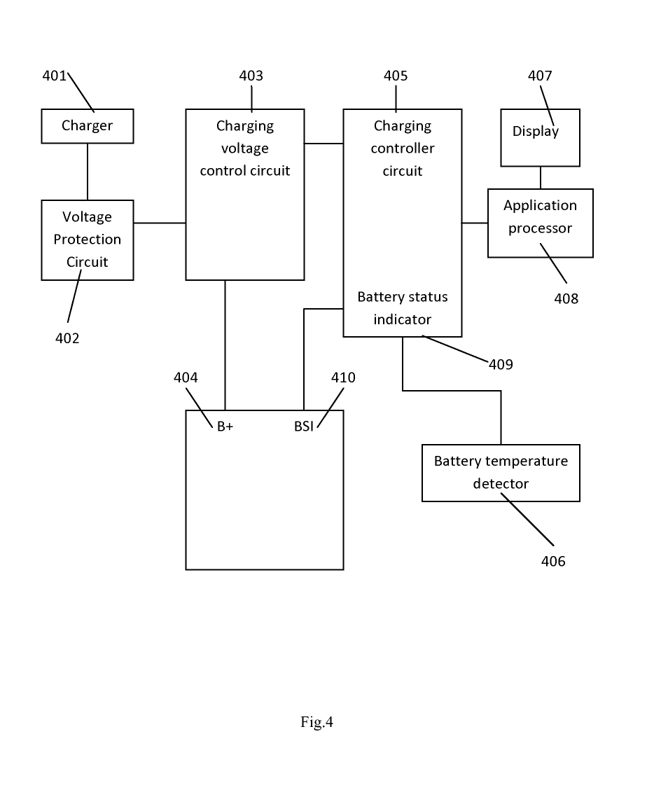

With reference to FIG. 4, charger 401 is connected to charging voltage control circuit 403, through voltage protection circuit 402. While controlled by charging controller circuit 405, charging voltage control circuit 403 controls B+ 404. Battery status indicator 409 is connected to the corresponding BSI 410 and battery temperature detector 406. Application processor 408 is the brain of all the circuits and decides if all the data are in correct or right information to begin the process. It always relies on the data sent by the charging controller circuit 405, then completely process it and output to display 407.

An embodiment of the present patent application involves extending traditional charger to nano-coating for better efficiency.

According to an embodiment of the present patent application, the final humidity and temperature, is adjusted to effectively reach a compromise between charger performance and the ease of operation.

Implementations of the embodiments of the present patent application disclosed herein may also be useful for future Internet of Things communication, where unattended sensors need charging controlling by the machine itself.

The silicon charger principles disclosed herein are also substantially independent of system architecture and may be used for virtually all embedded devices need the charge control.

One basic rule which could be implemented in accordance with an implementation of the embodiments of the present patent application is when the temperature difference becomes too low, water can be used as coolant.

The specific type of each component will be implementation-dependent. The particular structure and operation of the cool-hot pairs may be different for different formats of mechanical designs.

In addition, the present patent application is in no way restricted to implementation with mobile devices or other types of device having the specific structure shown in the drawings. Different or fewer components, with different sensor and actuator interconnections, may be used in a device in which an implementation of the present patent application can be done.

According to another embodiment, a single device incorporates both portable charger, with the projecting devices, can be built to form the said multi-function products with any smart phone, with corresponding applications, to fulfill the bright projector applications.

In one proto-type system, part of the projector is sourced from TI DLP6401 processor, the coloring flash is provided by QuickLogic DSI-RGB bridge, both WiFi and LTE are from Qualcomm, the charger diode pair is from Maxim.

Many different types of implementation and realization of the present patent application are possible, e.g. the humidity sensor can be included to detect the wet level, once the dry condition is detected, the reminding beep is sound to remind the user.

Components or devices described as hardware above may alternatively be implemented partially in application software. Similarly, method steps disclosed herein may be performed by hardware or implemented in software code.

While the present patent application has been shown and described with particular references to a number of embodiments thereof, it should be noted that various other changes or modifications may be made without departing from the scope of the present invention.

### REFERENCES

^{[1]}Sheetak, Inc., “Fuel-flexible thermal power generator for electric loads”, WO2014084897.

^{[2]}Hiroaki Takamatsu, “Cooling system for a video projector”, U.S. Pat. No. 6,254,238B1, 2001.

^{[3]}Hidemi Sasaki, Shinji Suzuki, “Video projector with battery and replaceable lamp unit”, U.S. Pat. No. 5,347,324A, 1994.

What is claimed is:

1. A system for air cooling or water cooling with silicon thermal charging diode, the system comprising: a heating dissipating device; and at least one cooling device; wherein the cooling device is configured to communicate with each of the at least one humid sensor device, to determine a current environment between the lighting device and the printed circuit board and to control the operating mode of the charging device according to the temperature difference.

2. The system of claim 1, wherein the projecting device is configured to sense the environment conditions such as wet or dry through at least one of the humidity sensor, to detect if water coolant needs to be added.

3. The system of claim 2, wherein the cooling device and each of the heating device is configured to perform temperature difference needed for generating electricity.

4. The system of claim 1, wherein the heating device and each of the cooling device is configured to form a dry and wet pair.

5. The system of claim 3, wherein the projecting device and mobile charging device are configured to deal with the charging and projecting at the same time.

6. The system of claim 3, wherein the dry pad is made of the water proof material, wet pad is made of hydrophilic material.

7. The system of claim 1, wherein the stand alone projecting device is paired up with any smart phone with related application to form the projecting system.

8. A method for charging through silicon thermal diode cooling system comprising the steps of:
humid sensor sensing
communicating with humid senor device
start up charge control manager
check cooling condition
turn on generator
check charging condition
Android VI show charging.
